(19) United States
(12) Patent Application Publication
(10) Pub. No.: US 2012/0281382 A1
(43) Pub. Date: Nov. 8, 2012

(54) ELECTRONIC DEVICE HAVING A PROJECTION MODULE

(75) Inventors: CHEN-TSAIR TSAI, TAIPEI (TW); CHUN-CHENG HUANG, TAIPEI (TW)

(73) Assignees: LITE-ON TECHNOLOGY CORP., TAIPEI (TW); SILITEK ELECTRONIC (GUANGZHOU) CO., LTD., GUANGZHOU (CN)

(21) Appl. No.: 13/281,532

(22) Filed: Oct. 26, 2011

(30) Foreign Application Priority Data
May 3, 2011 (CN) 201120148970.8

(51) Int. Cl. H05K 7/02

(52) U.S. Cl. 361/807

(57) ABSTRACT

An electronic device includes a host, a display, a pivoting mechanism, and a projection module. The display is connected rotatably to the host. The display includes a display housing having an upper side frame. The pivoting mechanism includes a hinge connected rotatably to the upper side frame. The projection module is connected to the hinge, in such a manner to allow for rotation of the projection module relative to the display housing about first and second axes that are perpendicular to each other.

### CROSS-REFERENCE TO RELATED APPLICATION

This application claims priority of Chinese Application No. 201120148970.8, filed on May 3, 2011.

### BACKGROUND OF THE INVENTION

1. Field of the Invention

This invention relates to an electronic device, and more particularly to an electronic device having a projection module.

2. Description of the Related Art

A portable electronic device, such as a note-book computer, typically includes a built-in projection module. The projection direction and angle of the portable electronic device are adjustable. The projection module is used to project images from the electronic device onto a cloth screen or a wall for presentation.

The projection module of a first conventional portable electronic device is disposed on a host, so that the position of the projection module and the height of images projected from the projection module are relatively low, and the images projected are obstructed easily. Furthermore, since the projection module is adjacent to the keyboard of the host, during use of the keyboard, the positions of the hands of the user are affected by the projection modules. The projection module of a second conventional electronic device is disposed on a display housing. However, due to the manner in which the projection module and the display housing are interconnected, the projection module can be rotated within only a limited angle. As a result, the projection direction and angle are limited.

### SUMMARY OF THE INVENTION

The object of this invention is to provide an electronic device that includes a projection module, the projection angle of which can be adjusted in a plurality of directions, in such a manner that images projected from the projection module cannot be obstructed.

According to an aspect of this invention, there is provided an electronic device comprising:

a host;

a display connected pivotally to an end of the host and including a display housing having an upper side frame;

a pivoting mechanism including a hinge connected rotatably to the upper side frame; and

a projection module connected removably to the hinge and rotatable relative to the display housing about first and second axes that are perpendicular to each other.

According to another aspect of this invention, there is provided an electronic device comprising:

a host;

a display connected rotatably to an end of the host and including a display housing having a hollow upper side frame;

a pivoting mechanism including a hinge connected rotatably to the upper side frame, the hinge being formed with a cable passage in spatial communication with the hollow upper side frame; and

a projection module connected to the hinge and rotatable relative to the host housing about first and second axes that are perpendicular to each other, the projection module including a transmission cable extending through the cable passage and electrically connected to the host for transmitting electric signals and electric energy to the projection module.

According to still another aspect of this invention, there is provided an electronic device comprising:

a host including a host housing formed with a main receiving groove having an upper end opening;

a display including a display housing connected rotatably to an end of the host housing, the display housing having a hollow upper side frame;

the pivoting mechanism including a hinge connected rotatably to the upper side frame, the hinge being formed with a cable passage in spatial communication with the hollow upper side frame; and

a projection module connected to the hinge and rotatable relative to the display housing about first and second axes that are perpendicular to each other, the projection module including a transmission cable extending through the cable

Passage and electrically connected to the projection module such that, when the display is covered on the host, the projection module is moved entirely into the main receiving groove via the upper end opening.

Since the projection module is disposed on the upper side frame of the display, the position of the projection module and the height of images projected from the projection module are comparatively high, and the images projected cannot be obstructed. Furthermore, since the projection module can rotate about the first and second axes, the projection angle of the projection module can be adjusted in a plurality of directions.

### BRIEF DESCRIPTION OF THE DRAWINGS

These and other features and advantages of this invention will become apparent in the following detailed description of the preferred embodiments of this invention, with reference to the accompanying drawings, in which:

FIG. 1 is a perspective view of the first preferred embodiment of an electronic device according to this invention;

FIG. 2 is a fragmentary, partly exploded perspective view of the first preferred embodiment;

FIG. 3 is an exploded perspective view of a pivoting mechanism of the first preferred embodiment;

FIG. 4 is a fragmentary perspective cutaway view of the first preferred embodiment;

FIG. 5 is a fragmentary front view of first preferred embodiment, illustrating that a top surface of an abutment wall of a shield of the pivoting mechanism is above two top surfaces of an upper side frame of a display;

FIG. 6 is a schematic perspective view of the first preferred embodiment, illustrating that a projection module is rotated about a second axis in a direction;

FIG. 7 is a view similar to FIG. 6 but illustrating the projection module is rotated about the second axis in an opposite direction;

FIGS. 8 and 9 are fragmentary side views of the first preferred embodiment, illustrating that the projection module is rotated about a first axis;

FIG. 10 is a fragmentary schematic view of the first preferred embodiment, illustrating that a cover plate is at a sealing position;

FIG. 11 is a fragmentary exploded perspective view of a host housing of the first preferred embodiment;

FIG. 12 is a fragmentary sectional view of the host housing of the first preferred embodiment, illustrating that the cover plate is at the sealing position;

FIG. 13 is a schematic view of the first preferred embodiment, illustrating that an outer housing of the projection module abuts against a front side of a display housing;

FIGS. 14 and 15 are fragmentary views of the first preferred embodiment, illustrating that the cover plate is at a concealed position, and the projection module is received within a main receiving groove;

FIG. 16 illustrates a modification to the projection module of the first preferred embodiment;

FIG. 17 is a perspective view of the second preferred embodiment of an electronic device according to this invention;

FIG. 18 is a fragmentary schematic view of the second preferred embodiment, illustrating that a cover plate is at a sealing position;

FIG. 19 is a fragmentary schematic view of the second preferred embodiment, illustrating that the cover plate is at a concealed position, and a projection module is received within a main receiving groove;

FIG. 20 is a fragmentary schematic view of the third preferred embodiment of an electronic device according to this invention, illustrating that a cover plate is at a sealing position;

FIG. 21 is a view similar to FIG. 20 but illustrating that the cover plate is at a concealed position;

FIG. 22 is a perspective view of the fourth preferred embodiment of an electronic device according to this invention;

FIG. 23 is a fragmentary, partly exploded perspective view of the fourth preferred embodiment;

FIG. 24 is an exploded perspective view of a pivoting mechanism of the fourth preferred embodiment;

FIG. 25 is a fragmentary perspective cutaway view of the fourth preferred embodiment;

FIGS. 26 and 27 are fragmentary schematic view of the fourth preferred embodiment, illustrating that a cover plate is at a concealed position, and a projection module is received within a main receiving groove;

FIG. 28 is a fragmentary schematic view illustrating a modified host housing of the fourth preferred embodiment; and

FIG. 29 is a fragmentary schematic view illustrating another modified host housing of the fourth preferred embodiment.

### DETAILED DESCRIPTION OF THE PREFERRED EMBODIMENTS

Before the present invention is described in greater detail in connection with the preferred embodiments, it should be noted that similar elements and structures are designated by like reference numerals throughout the entire disclosure.

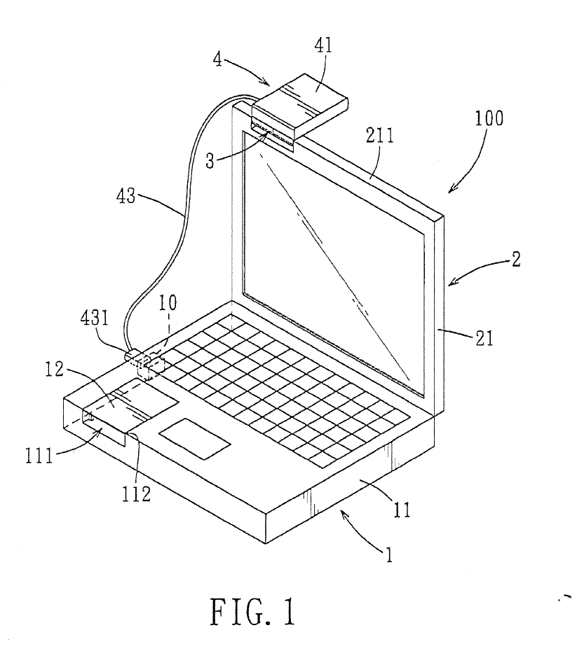

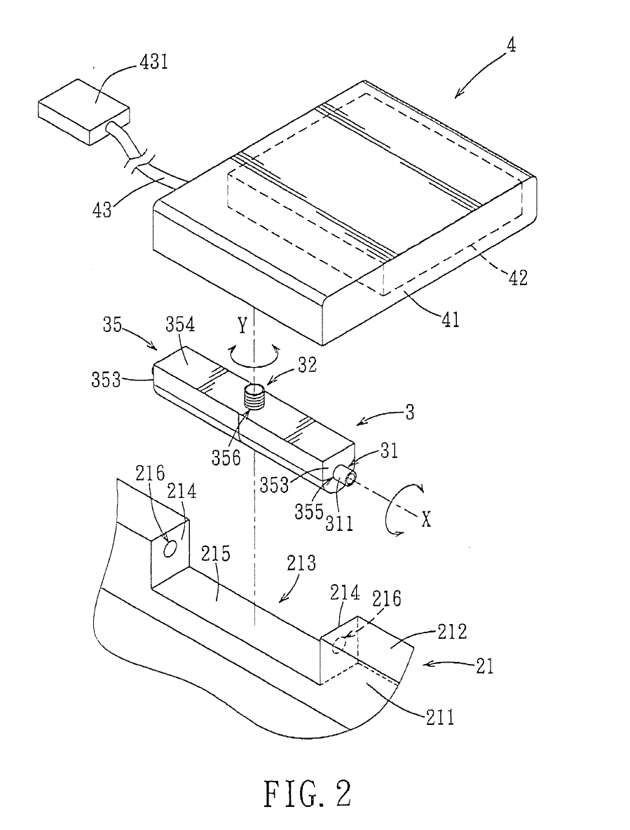

Referring to FIGS. 1 and 2, the first preferred embodiment of an electronic device 100 according to this invention is exemplified using a note-book computer, and includes a host 1, a display 2, a pivoting mechanism 3, and a projection module 4.

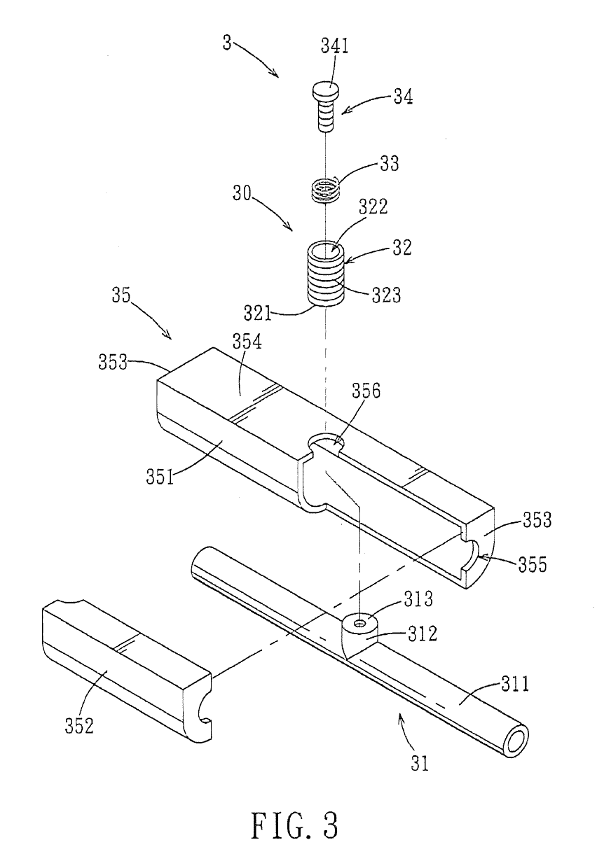

With additional reference to FIG. 3, the display 2 is connected rotatably to an end of the host 1, and includes a host housing 21 having an upper side frame 211. The pivoting mechanism 3 includes a hinge 30. The projection module 4 is used to project images therefrom, is connected removably to the hinge 30, and is rotatable relative to the display housing 21 about first and second axes (X, Y) so as to allow for adjustment of the projection angle of the projection module 4 in a plurality of directions.

The construction and operation of the electronic device 100 will be described in the following.

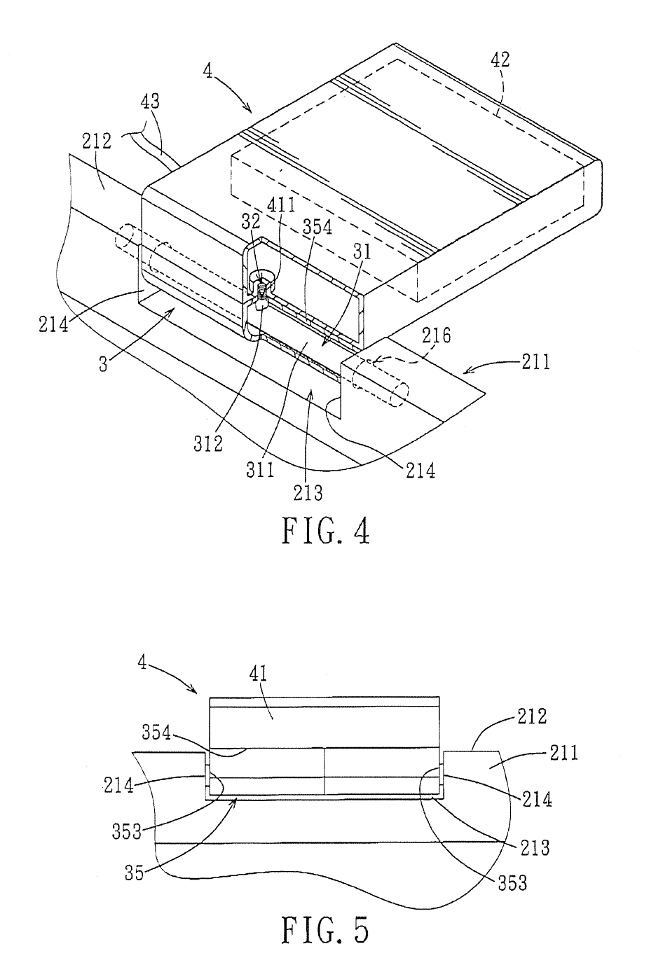

With further reference to FIG. 4, the upper side frame 211 of the display housing 21 includes two aligned top surfaces 212 spaced apart from each other in a left-to-right direction, and an accommodating groove 213 that is disposed between the top surfaces 212 and that is defined by two opposite side wall surfaces 214 extending respectively and downwardly from inner ends of the top surfaces 212, and a bottom wall surface 215 interconnecting bottom ends of the side wall surfaces 214. As such, the accommodating groove 213 has an open upper end and open front and rear sides.

The hinge 30 includes a first pivot member 31. The first pivot member 31 includes a cylindrical pivot rod 311 and a cylindrical coupling rod 312 extending perpendicular from an outer surface of a middle portion of the pivot rod 311. Each of the side wall surfaces 214 of the upper side frame 211 is formed with a pivot hole 216. The pivot rod 311 of the first pivot member 31 has left and right ends that are received respectively and rotatably within the pivot holes 216 in the side wall surfaces 214. The first axis (X) is constituted by the central axis of the pivot rod 311. That is, the first pivot member 31 is rotatable relative to the upper side frame 211 about the first axis (X).

The hinge 30 further includes a second pivot member 32, a compression spring 33, and a connecting member 34. The second pivot member 32 is configured as a hollow cylinder, and has a bottom surface 321 abutting against atop surface 313 of the coupling rod 312. Preferably, the bottom surface 321 and the top surface 313 are uneven complementary surfaces so as to maintain relative position therebetween. The connecting member 34 extends through the compression spring 33 and a central bore 322 in the second pivot member 32 to connect with the coupling rod 312 for connecting the second pivot member 32 to the coupling rod 312, in such a manner that the second pivot member 32 can rotate relative to the coupling rod 312. The second axis (Y) is constituted by the central axis of the second pivot member 32. In this embodiment, the connecting member 34 is a bolt, and is threaded to the coupling rod 312.

The compression spring 33 has upper and lower ends abutting respectively against a head of the connecting member 34 and a shoulder (not shown) formed in the central bore 322 in the second pivot member 32 for biasing the bottom surface 321 of the second pivot member 32 to contact the top surface 313 of the coupling rod 312.

In this embodiment, the projection module 4 is an external projector, and includes an outer housing 41 connected removably to the hinge 30, a projection unit 42 disposed within the outer housing 41 for projecting images therefrom, and a transmission cable 43 extending through the outer housing 41. The projection module 4 further includes a memory unit (not shown) storing image data and electrically connected to the projection unit 42. The image data can be stored in the memory unit through a transmission interface (not shown) of the projection module 4. Hence, the projection unit 42 can project the stored image data. One end of the transmission cable 43 is electrically connected to the projection unit 42. The other end of the transmission cable 43 is provided with an electric plug 431. The host 1 includes a host housing 11 connected rotatably to the display housing 21, and an electric connector 10 (e.g. USE electric connector) exposed from a side of the host housing 11. The electric plug 431 is inserted removably into the electric connector 10 of the host 1, so that the transmission cable 43 can transmit electric energy to the projection unit 42.

Due to the presence of the first and second pivot members 31, 32, the projection module 4 can rotate relative to the display housing 21 about the first and second axes (X, Y).

In this embodiment, the second pivot member 32 has an externally threaded portion 323. The outer housing 41 of the projection module 4 has a bottom surface that is formed with a threaded hole 411 engaging the externally threaded portion 323 of the second pivot member 32, so as to connect the outer housing 41 removably to the second pivot member 32. Since the outer housing 41 is mounted removably to the second pivot member 32, and since the electric plug 431 of the transmission cable 43 is inserted removably into the electric connector 30, when it is desired to use the projection module 4, the projection module 4 can be mounted conveniently and rapidly to the hinge 30 of the pivoting mechanism 3, so that the projection angle of the projection module 4 can be adjusted in a plurality of directions through the hinge 30, in such a manner that an assembly of the host 1 and the display 2 serves as a support foot. When the projection module 4 is no longer used, it can be removed conveniently and rapidly from the hinge 30.

With further reference to FIG. 5, the pivoting mechanism 3 further includes a shield 35. The shield 35 includes a first shielding body 351 and a second shielding body 352 snap fitted to the first shielding body 351. An assembly of the first and second shielding bodies 351, 352 is sleeved on the hinge 30, and has a pair of left and right end walls 353 and a flat abutment wall 334 connected between the end walls 353 and permitting the outer housing 41 to abut thereagainst. Each of the end walls 353 is formed with an opening 355 permitting extension of the pivot rod 311 of the first pivot member 31 therethrough. Two ends of the pivot rod 311 are disposed outwardly of the openings 355, respectively, and are received rotatably within the pivot holes 216 in the side wall surfaces 214, respectively. The abutment wall 354 has a through hole 356 formed therethrough and permitting the second pivot member 32 to extend therethrough to engage the threaded hole 411 in the outer housing 41.

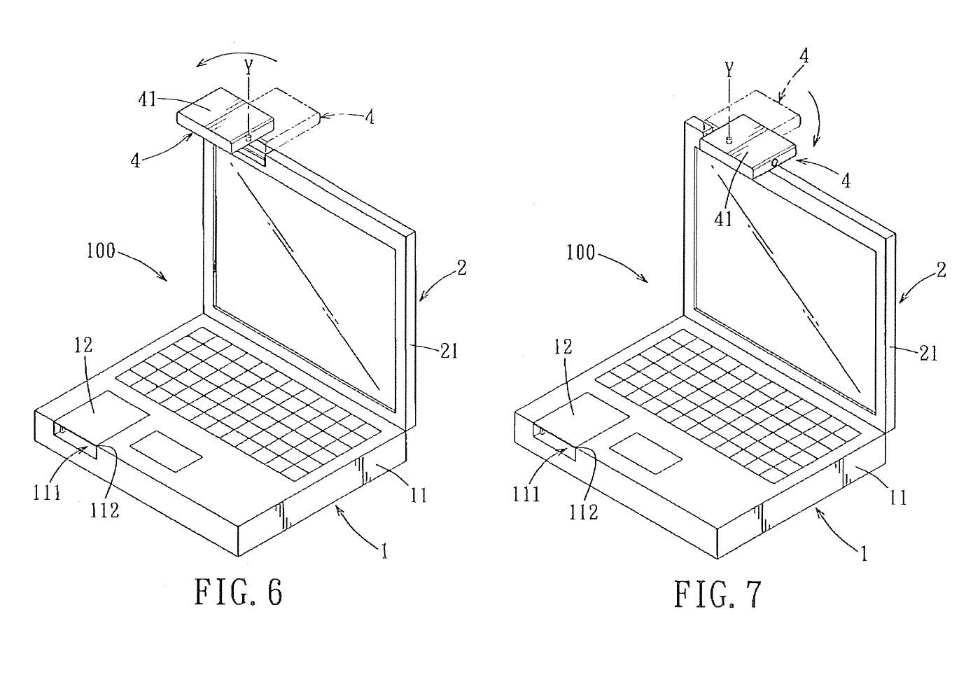

An assembly of the hinge 30 and the shield 35 is rotatable relative to the upper side frame 211 about the first axis (X), as described above. When the shield 35 is rotated about the first axis (X) to an angular position shown in FIG. 5, where a top surface of the abutment wall 354 of the shield 35 is parallel to the top surfaces 212 of the upper side frame 211, the top surface of the abutment wall 354 is not below the top surfaces 212 of the upper side frame 211, so that the bottom surface of the outer housing 41 is above the top surfaces 212. As such, the projection module 4 can be rotated rightwardly about the second axis (Y) in a counterclockwise direction shown in FIG. 6 or leftwardly about the second axis (Y) in a clockwise direction shown in FIG. 7, such that it is not obstructed by the side wall surfaces 214. As a result, the projection angle of the projection module 4 is not limited by the display housing 21. In this embodiment, the top surface of the abutment wall 354 is above the top surfaces 212 of the upper side frame 211.

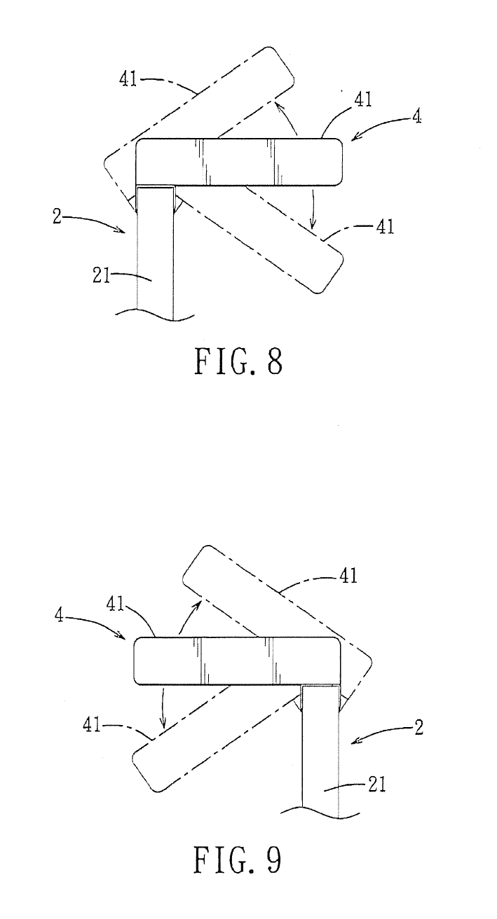

Referring to FIGS. 8 and 9, the projection module 4 can be rotated about the first axis (X) (see FIG. 2) in a clockwise or counterclockwise direction. In this manner, a projector lens (not shown) of the projection module 4 can be adjusted to face forwardly or rearwardly. Since the pivoting mechanism 3 is disposed pivotally on the upper side frame 211 of the display housing 21, and since the projection module 4 is disposed on the pivoting mechanism 3, the position of the projection module 4 is comparatively high. Thus, the height of the images projected from the projection module 4 is also comparatively high, and cannot be obstructed.

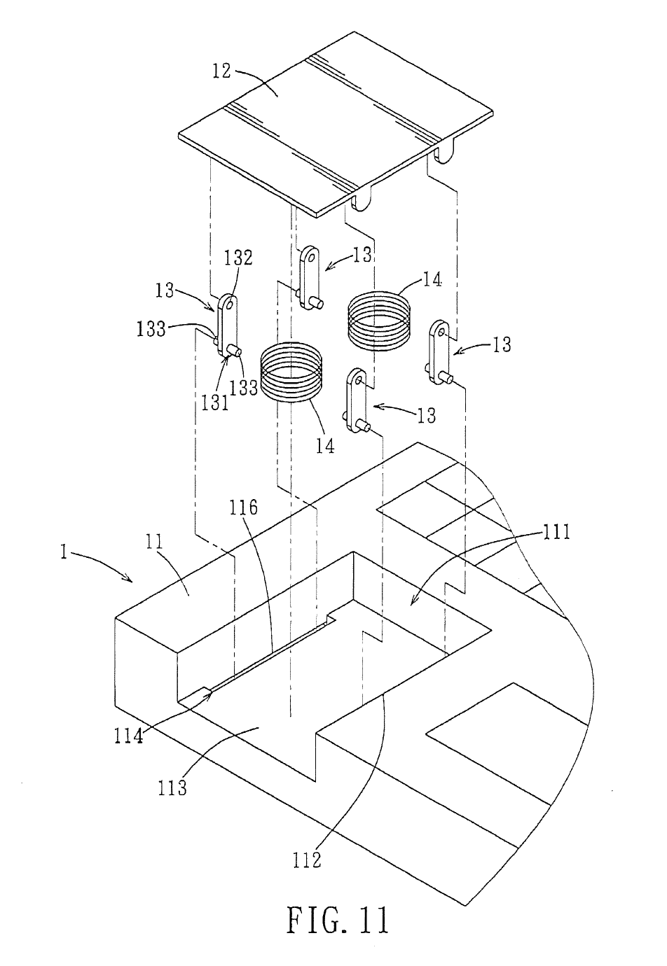

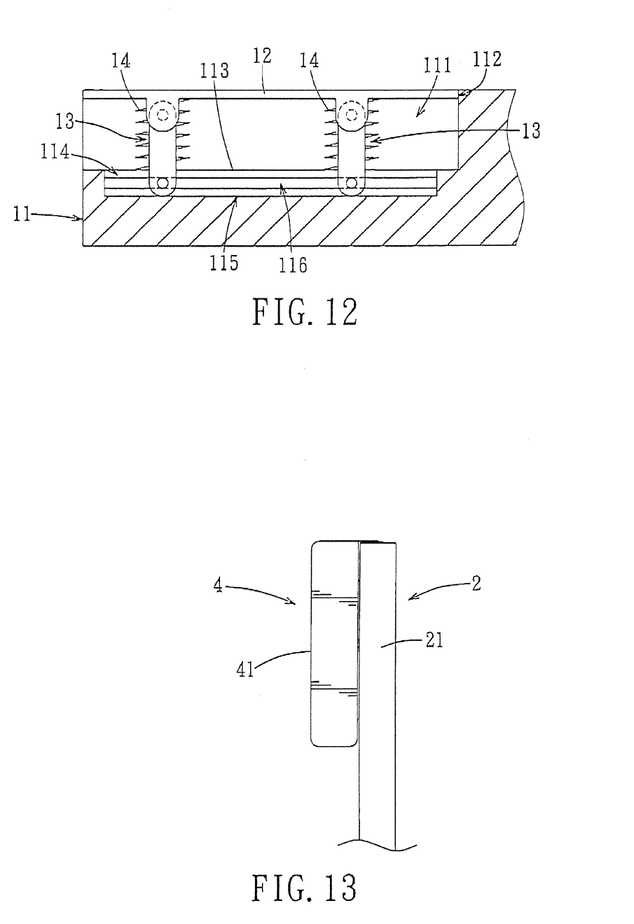

Referring to FIGS. 1, 10, 11, and 12, to receive the projection module 4 when the display 2 is covered on the host 1, in this embodiment, the host housing 11 is formed with a main receiving groove 111 having an upper end opening 112. When the display 2 is covered on the host 1, the projection module 4 is moved entirely into the main receiving groove 111 via the upper end opening 112 so as not to project from a back surface of the display housing 21. The host 1 further includes a cover plate 12 disposed on the host housing 11 for sealing removably the upper end opening 112 of the main receiving groove 111. When the projection module 4 is received within the main receiving groove 111, the cover plate 12 can be used to seal the upper end opening 112 so as to maintain a good appearance of the host 1.

In this embodiment, the host housing 1 includes a bottom wall 113 that is formed with a pair of left and right slide slots 114 spaced apart from each other and in spatial communication with the main receiving groove 111. The host 1 further includes two pairs of connecting rods 13, which are disposed respectively under left and right side portions of the cover plate 12 and each of which are spaced apart from each other along a front-to-rear direction. Each of the connecting rods 13 has a lower pivot portion 131 disposed rotatably and movably in the corresponding slide slot 114, and an upper pivot portion 132 connected pivotally to the cover plate 12. When the projection module 4 is pressed downwardly against the cover plate 12, the connecting rods 13 are moved entirely into the slide slots 114 to allow for downward movement of the projection module 4 within the main receiving groove 111. In this manner, the projection module 4 can be moved entirely into the main receiving groove 111 via the upper end opening 112. Each of the slide slots 114 has a horizontal accommodating slot portion 115 extending along the front-to-rear direction, and two guide slot portions 115 in spatial communication with left and right sides of the accommodating slot portion 115, respectively. Each of the connecting rods 13 further has a pivot hole formed in the upper pivot portion 132 and engaging a pivot pin 121 of the cover plate 12, and two pivot pins 133 formed respectively at left and right sides of the lower pivot portion 131. The pivot pins 133 of the connecting rods 13 are received respectively, rotatably, and movably in the guide slot portions 116 of the slide slots 114. As such, each of the connecting rods 13 is rotatable about a common central axis of the corresponding pivot pins 133, and the pivot pins 133 are movable respectively along the guide slot portions 116, so as to allow the connecting rods 13 to move entirely into the accommodating slot portions 115.

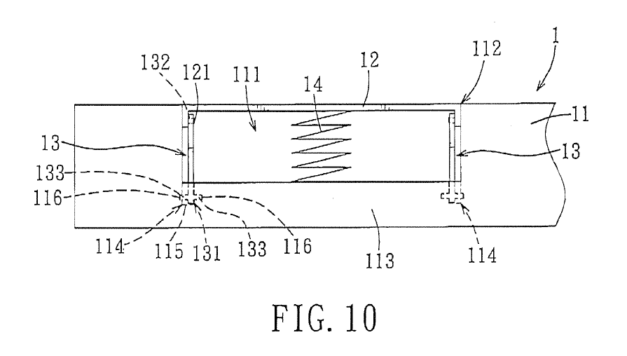

The host 1 further includes two biasing springs 14 disposed on the bottom wall 113 and spaced apart from each other along the front-to-rear direction. Each of the biasing springs 14 is configured as a compression spring, and has a bottom end secured to the bottom wall 113, e.g., by soldering, and a top end abutting against a bottom surface of the cover plate 12. As such, the biasing springs 14 can bias the cover plate 12 to move upwardly to a sealing position shown in FIG. 10 for sealing the upper end opening 112. When the cover plate 12 is at the sealing position, the connecting rods 13 project from the slide slots 114, and are vertical. It should be noted that, the number of the connecting rods 13 and the biasing springs 14 can be changed. In an alternative embodiment, the host I includes two connecting rods 13 connected respectively and pivotally to the left and right side portions of the cover plate 12, and only one biasing spring 14.

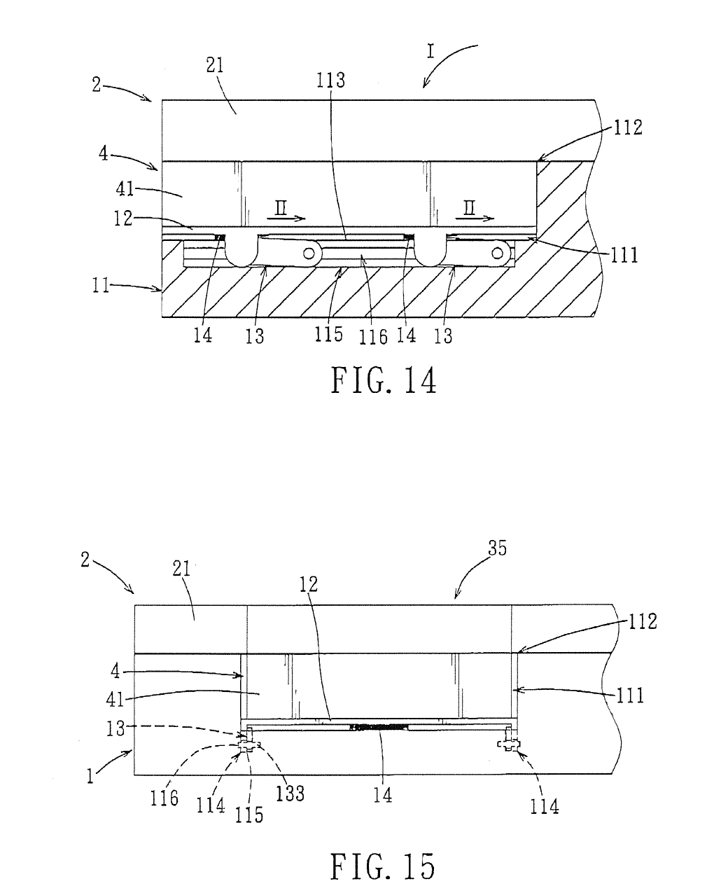

With particular reference to FIGS. 13, 14, and 15, when it is desired to cover the display 2 on the host 1 in such a manner to conceal the projection module 4 between the display 2 and the host 1, the projection module 4 is first rotated to abut against a front side of the display housing 21, as shown in FIG. 13. Next, the display housing 21 is rotated toward the host 1 in a direction (I) (see FIG. 14). Since the guide slot portions 116 limit the moving direction of the pivot pins 133. When a downward force is applied from the outer housing 41 of the projection module 4 to the cover plate 12, each of the connecting rods 13 is rotated about the central axes of the corresponding pivot pins 133 in the direction (I), and each of the pivot pins 133 is moved rearwardly. At the same time, the biasing springs 14 are compressed by the cover plate 12. When the display 2 is rotated to cover the host 1 and press against a top end of the host housing 11, the cover plate 12 is moved to a concealed position shown in FIG. 15, where the cover plate 12 is adjacent to the bottom wall 113. In the concealed position, the connecting rods 13 are horizontal, and are received within the accommodating slot portions 115, and the projection module 4 is received entirely within the main receiving groove 111.

When the display housing 2 is rotated in a direction opposite to the direction (I) to remove the projection module 4 from the main receiving groove 111, the cover plate 12 is biased by the biasing springs 19 to move upwardly. Hence, each of the connecting rods 13 is rotated about the common central axis of the corresponding pivot pins 133 in the direction opposite to the direction (I), and the pivot pins 133 move forwardly along the guide slot portions 116. Consequently, the cover plate 12 is moved back to the sealing position for sealing the upper end opening 112.

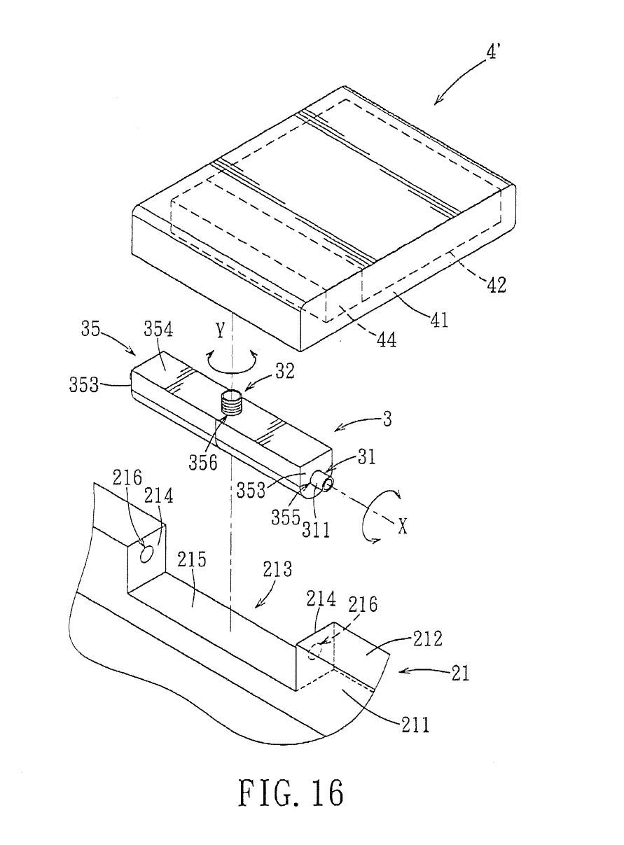

FIG. 16 shows a modified projection module 4′, which includes a battery set 49 disposed within the outer housing 41 and electrically connected to the projection unit 42. As such, the battery set 44 can supply electric energy to the projection unit 42.

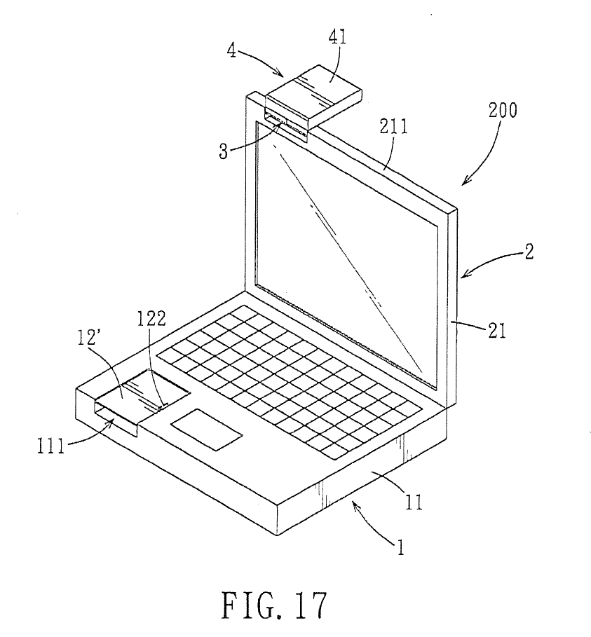

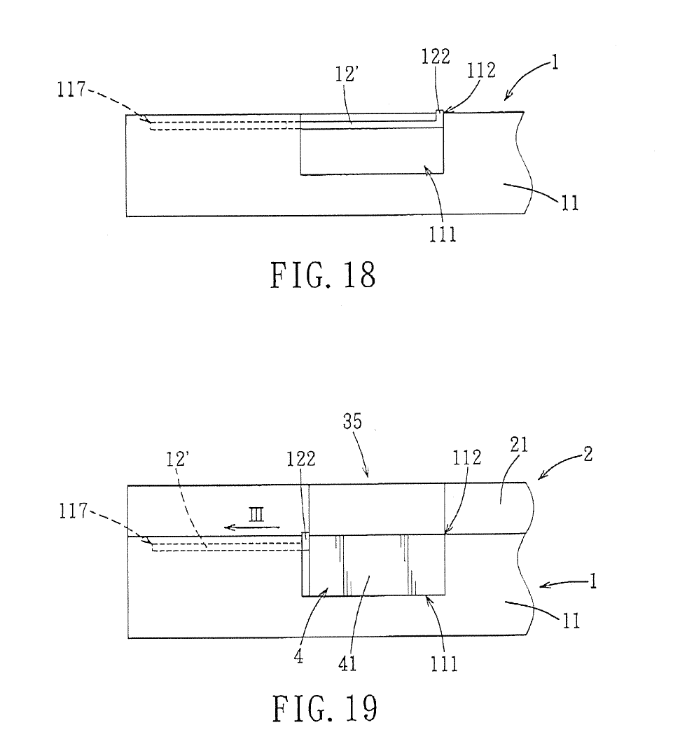

FIGS. 17 and 18 show the second preferred embodiment of an electronic device 200 according to this invention, which is similar in construction to the first preferred embodiment except that, the cover plate 12′ is received in a different manner.

In this embodiment, the host housing 11 is further formed with a side receiving groove 117 that is in spatial communication with a side of the main receiving groove 111 and that is horizontal. The cover plate 12′ is movable from the upper end opening 112 to a concealed position shown in FIG. 19 whereat the cover plate 12′ is received entirely within the side receiving groove 117, and has a top surface formed with a protrusion 122 for manual operation.

Referring to FIG. 19, when it is desired to cover the display 2 on the host 1 and receive the projection module 4 within the host 1, a force is applied to the protrusion 122 of the cover plate 12′ in a horizontal direction (III) to move the cover plate 12′ into the side receiving groove 117. Subsequently, the display 2 is rotated toward the host 1. Upon contact of the display 2 with the host housing 11 to cover the host 1, the projection module 4 is received entirely within the main receiving groove 111.

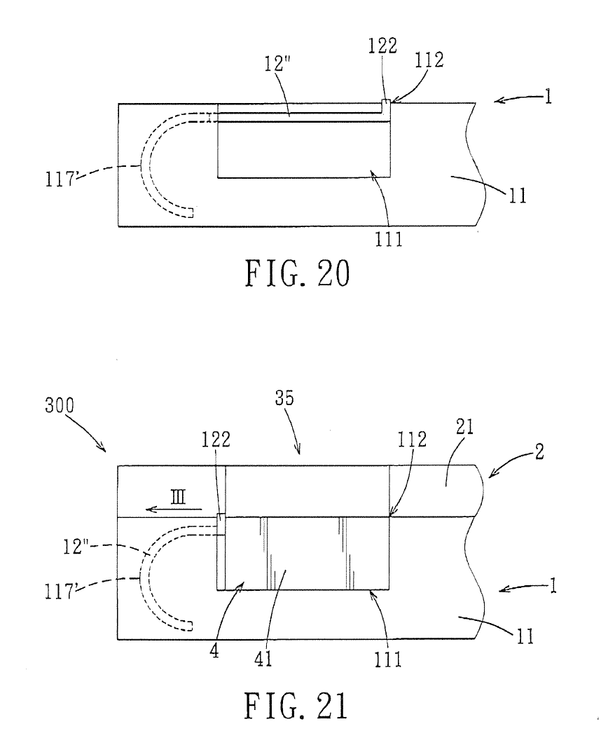

FIGS. 20 and 21 show the third preferred embodiment of an electronic device 300 according to this invention, which is similar in construction to the second preferred embodiment and which differs from the second preferred embodiment in the shape of the side receiving groove 117′.

In this embodiment, the side receiving groove 117′ is curved, and the cover plate 12″ is a flexible plate. When it is desired to cover the display 2 on the host 1 and receive the projection module 4 in the host 1, a force is applied to the protrusion 122 of the cover plate 12″ in the horizontal direction (III) to move the cover plate 12″. Hence, the cover plate 12″ is flexed to move entirely into the side receiving groove 117′. Subsequently, the display 2 is rotated toward the host 1. Upon contact of the display 2 with the host housing 11 to cover the host 1, the projection module 4 is received entirely within the main receiving groove 111.

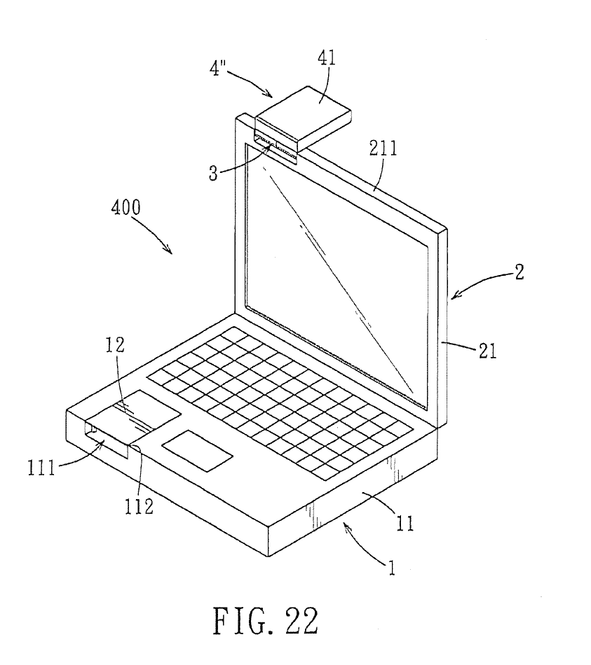

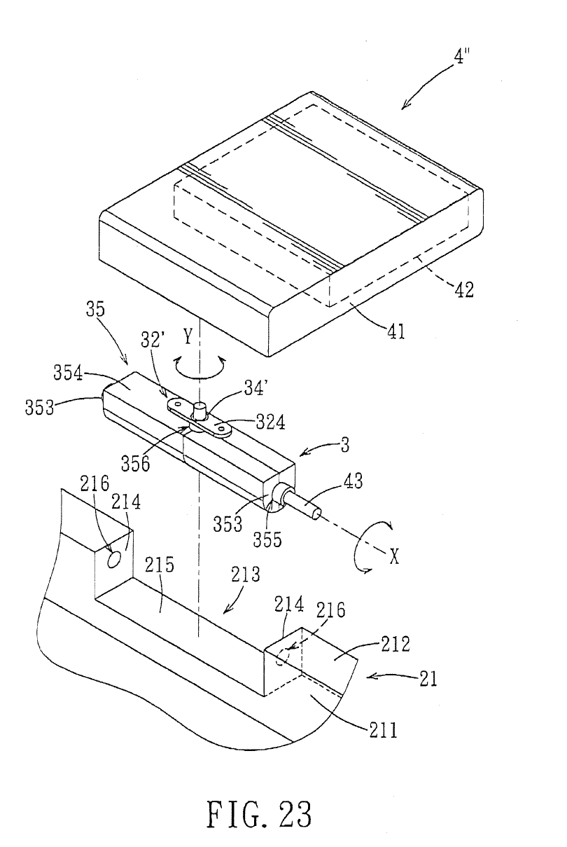

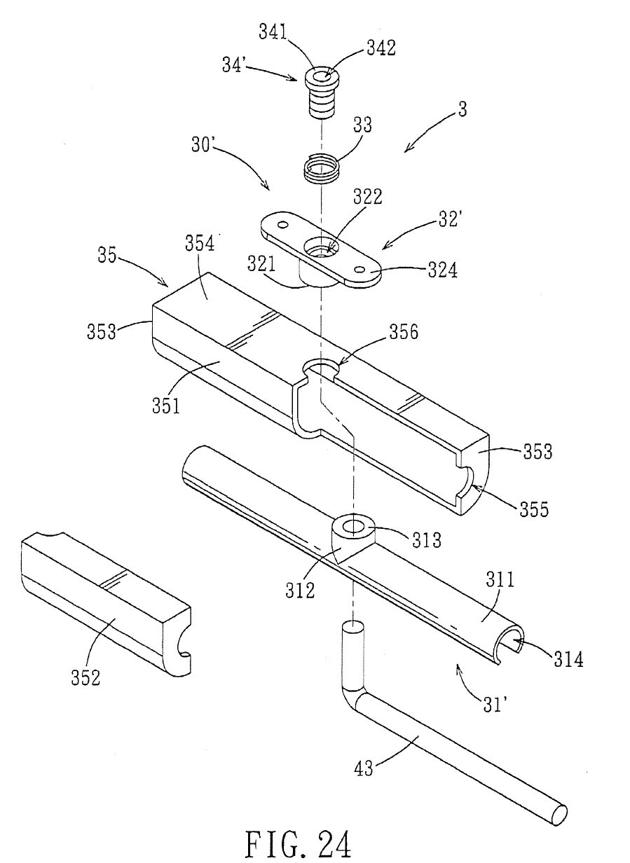

FIGS. 22, 23, and 24 show the third preferred embodiment of an electronic device 400 according to this invention, which is similar in construction to the first preferred embodiment except for the design of the hinge and the projection module 4″.

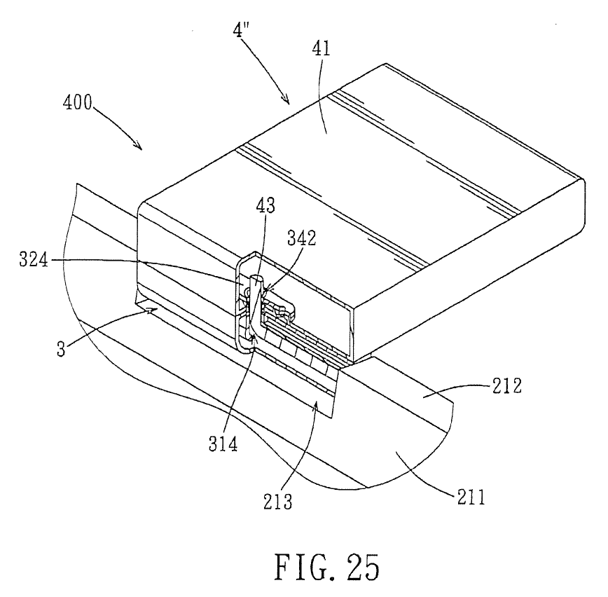

With further reference to FIG. 25, in this embodiment, the upper side frame 211 is hollow, and the second pivot member 32′ includes a coupling plate portion 324 connected removably to the outer housing 41 of the projection module 4″ by bolts. The first pivot member 31′ has an interior hole 314 formed through the pivot rod 311 and the coupling rod 312 and in spatial communication with the hollow upper side frame 211. The connecting member 34′ has a penetration hole 342 formed therethrough and in spatial communication with the interior hole 314 and the outer housing 41. The interior hole 314 cooperates with the penetration hole 342 to constitute a cable passage. The projection module 4″ is a built-in projector for projecting image data stored in a hard disk (not shown) of the host 1. The transmission cable 43 of the projection module 4″ extends through the cable passage, and is electrically connected between a circuit board (not shown) of the host 1 and the projection unit 42 for transmitting electric signals and electric energy to the projection unit 42. Since the transmission cable 43 extends through the cable passage, it can be prevented from damage and breakage caused due to excessive rotation.

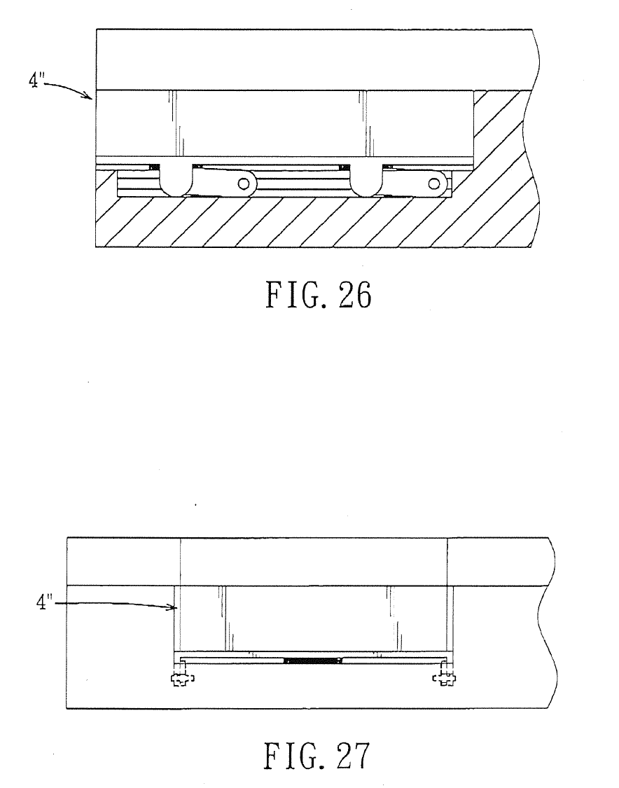

In this embodiment, the projection module 4″ is received within the main receiving groove in the same manner as the first preferred embodiment, as shown in FIGS. 26 and 27.

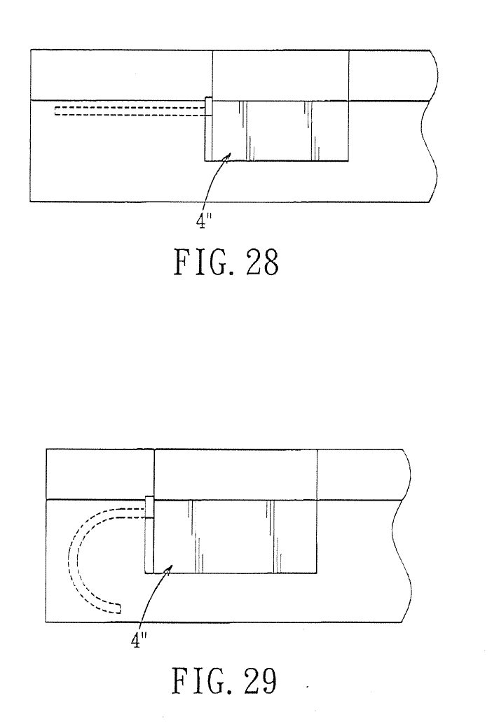

Alternatively, the projection module 4″ may be received within the main receiving groove in the same manner as the second preferred embodiment, as shown in FIG. 28, or as the third preferred embodiment, as shown in FIG. 29.

In view of the above, in the electronic device 100, 200, 300, 400 of this invention, by mounting the pivoting mechanism 3 pivotally to the upper side frame 211 of the display housing 21 and mounting the projection module 4, 4′, 4″ to the pivoting mechanism 3, the height of the projection module 4, 4′, 4″ is increased significantly, so as to prevent images projected from the projection module 4 from being obstructed. Furthermore, since the projection module 4, 4′, 4″ can rotate about the first and second axes (X, Y), the projection angle of the projection module 4, 4′, 4″ can be adjusted in a plurality of directions.

Further, due to the design of the main receiving groove 111 in the host housing 11, when the display 2 is covered on the host 1, the projection module 4, 4′, 4″ can be concealed within the host housing 11, thereby resulting in convenience during use of the electronic device 100, 200, 300, 400. Thus, the object of this invention is achieved.

With this invention thus explained, it is apparent that numerous modifications and variations can be made without departing from the scope and spirit of this invention, it is therefore intended that this invention be limited only as indicated by the appended claims.

We claim:

1. An electronic device comprising:
a host;
a display connected pivotally to an end of said host and including a display housing having an upper side frame;
a pivoting mechanism including a hinge connected rotatably to said upper side frame; and
a projection module connected removably to said hinge and rotatable relative to said display housing about first and second axes that are perpendicular to each other.

2. The electronic device as claimed in claim 1, wherein said host includes an electric connector, and said projection module includes an outer housing connected removably to said hinge, a projection unit disposed within said outer housing, and a transmission cable electrically connected to said projection unit, said transmission cable having an electrical plug inserted removably into said electric connector for transmitting electric energy to said projection unit.

3. The electronic device as claimed in claim 1, wherein said projection unit includes an outer housing connected removably to said hinge, a projection unit disposed within said outer housing, and a battery set disposed within said outer housing and electrically connected to said projection unit for supplying electric energy to said projection unit.

4. The electronic device as claimed in claim 1, wherein said hinge includes a first pivot member connected rotatably to said upper side frame and having a central axis constituting said first axis, and a second pivot member connected rotatably to said first pivot member, connected to said outer housing, and having a central axis constituting said second axis, said second pivot member being cylindrical and being externally threaded, said outer housing being formed with a threaded hole engaging said second pivot member.

5. The electronic device as claimed in claim 4, wherein said upper side frame is formed with an accommodating groove that has an open upper end and two opposite open sides, that is defined by two opposite side wall surfaces and a bottom wall surface interconnecting bottom ends of said side wall surfaces, and that receives said hinge, said first pivot member being connected pivotally to said side wall surfaces.

6. The electronic device as claimed in claim 5, wherein said pivoting mechanism further includes a shield sleeved on said hinge, said shield including an abutment wall permitting said outer housing to abut thereagainst, said abutment wall having a top surface and being formed with a through hole permitting said second pivot member to extend outwardly from said shield therethrough, said upper side frame having two aligned top surfaces extending respectively and outwardly from said side wall surfaces, said shield being rotatable relative to said upper side frame to an angular position, where said top surface of said abutment wall is parallel to said top surfaces of said upper side frame and where said top surface of said abutment wall is not below said top surfaces of said upper side frame.

7. The electronic device as claimed in claim 1, wherein said host includes a host housing connected pivotally to said display and formed with a main receiving groove, said main receiving groove having an upper end opening that is positioned such that, when said display is pivoted to cover said host, said projection module is moved entirely into said main receiving groove via said upper end opening.

8. The electronic device as claimed in claim 7, wherein said host further includes a cover plate disposed on said host housing and movable to seal said upper end opening.

9. The electronic device as claimed in claim 8, wherein said host housing includes a bottom wall formed with two spaced-apart slide slots in spatial communication with said main receiving groove, said host further including at least two connecting rods and at least one biasing spring that are disposed under said cover plate, each of said connecting rods including a lower pivot portion disposed movably and rotatably within a respective one of said slide slots, and an upper pivot portion connected pivotally to said cover such that, when said display is covered on said host, said cover plate is pressed by said projection module to move downwardly within said main receiving groove until said connecting rods are moved respectively and entirely into said slide slots, said biasing spring being disposed on said bottom wall for biasing said cover plate upwardly to seal said upper end opening of said main receiving groove.

10. The electronic device as claimed in claim 9, wherein each of said slide slots has a horizontal accommodating slot portion for receiving a corresponding one of said connecting rods when said display is covered on said host, and a guide slot portion in spatial communication with a side of said accommodating slot portion, said lower pivot portion of each of said connecting rods having a pivot pin extending movably and rotatably within said guide slot portion of a corresponding one of said slide slots.

11. The electronic device as claimed in claim 8, wherein said host housing is further formed with a side receiving groove in spatial communication with said main receiving groove, such that said cover plate is movable from said upper end opening into said side receiving groove.

12. The electronic device as claimed in claim 11, wherein said cover plate has a top surface, and a protrusion formed on said top surface for manual operation.

13. The electronic device as claimed in claim 12, wherein said side receiving groove is horizontal.

14. The electronic device as claimed in claim 12, wherein said side receiving groove is curved, and said cover plate is a flexible plate.

15. An electronic device comprising:
a host;
a display connected rotatably to an end of said host and including a display housing having a hollow upper side frame;
a pivoting mechanism including a hinge connected rotatably to said upper side frame, said hinge being formed with a cable passage in spatial communication with said hollow upper side frame; and
a projection module connected to said hinge and rotatable relative to said host housing about first and second axes that are perpendicular to each other, said projection module including a transmission cable extending through said cable passage and electrically connected to said host for transmitting electric signals and electric energy to said projection module.

16. The electronic device as claimed in claim 15, wherein said projection module further includes an outer housing and a projection unit that is disposed within said outer housing and that is electrically connected to said transmission cable, said hinge including a first pivot member connected rotatably to said upper side frame and having a central axis constituting said first axis, and a second pivot member connected to said outer housing, and a connecting member interconnecting said first and second pivot members, said first pivot member having an interior hole formed therethrough and in spatial communication with said hollow upper side frame, said connecting member having a penetration hole formed therethrough and in spatial communication with said outer housing, said interior hole cooperating with said penetration hole to form said cable passage.

17. The electronic device as claimed in claim 16, wherein said upper side frame is formed with an accommodating groove that has an open upper end and two opposite open sides and that is defined by two opposite side wall surfaces to receive said hinge, each of said side wall surfaces being formed with a pivot hole, said first pivot member being received rotatably within said pivot holes in said side wall surfaces.

18. The electronic device as claimed in claim 17, wherein said pivoting mechanism further includes a shield sleeved on said hinge, said shield including an abutment wall permitting said outer housing to abut thereagainst, said abutment wall having a top surface and being formed with a through hole permitting said second pivot member to extend outwardly from said shield therethrough, said upper side frame having two aligned top surfaces extending respectively and outwardly from said side wall surfaces, said shield being rotatable relative to said upper side frame to an angular position, where said top surface of said abutment well is parallel to said top surfaces of said upper side frame and where said top surface of said abutment wall is not below said top surfaces of said upper side frame.

19. An electronic device comprising:
a host including a host housing formed with a main receiving groove having an upper end opening;
a display including a display housing connected rotatably to an end of said host housing, said display housing having a hollow upper side frame;
a pivoting mechanism including a hinge connected rotatably to said upper side frame, said hinge being formed with a cable passage in spatial communication with said hollow upper side frame; and
a projection module connected to said hinge and rotatable relative to said display housing about first and second axes that are perpendicular to each other, said projection module including a transmission cable extending through said cable passage and electrically connected to said projection module such that, when said display is covered on said host, said projection module is moved entirely into said main receiving groove via said upper end opening.

20. The electronic device as claimed in claim 19, wherein said host further includes a cover plate disposed on said host housing and sealing removably said upper end opening.

21. The electronic device as claimed in claim 20, wherein said host housing includes a bottom wall formed with two spaced-apart slide slots in spatial communication with said main receiving groove, said host further including at least two connecting rods and at least one biasing spring that are disposed under said cover plate, each of said connecting rods including a lower pivot portion disposed movably and rotatably within a respective one of said slide slots, and an upper pivot portion connected pivotally to said cover such that, when said display is covered on said host, said cover plate is pressed by said projection module to move downwardly within said main receiving groove until said connecting rods are moved respectively and entirely into said slide slots, said biasing spring being disposed on said bottom wall for biasing said cover upwardly to seal said upper end opening of said main receiving groove.

22. The electronic device as claimed in claim 21, wherein each of said slide slots has a horizontal accommodating slot portion for receiving a corresponding one of said connecting rods when said display is covered on said host, and a guide slot portion in spatial communication with a side of said accommodating slot portion, said lower pivot portion of each of said connecting rods having a pivot pin extending movably and rotatably within said guide slot portion of a corresponding one of said slide slots.

23. The electronic device as claimed in claim 20, wherein said host housing is further formed with a side receiving groove in spatial communication with said main receiving groove, such that said cover plate is movable from said upper end opening into said side receiving groove.

24. The electronic device as claimed in claim 23, wherein said cover plate has a top surface, and a protrusion formed on said top surface for manual operation.

25. The electronic device as claimed in claim 24, wherein said side receiving groove is horizontal.

26. The electronic device as claimed in claim 24, wherein said side receiving groove is curved, and said cover plate is a flexible plate.
